(19) United States
(12) Patent Application Publication
(10) Pub. No.: US 2018/0371613 A1
(43) Pub. Date: Dec. 27, 2018

(54) FILM DEPOSITION APPARATUS

(71) Applicant: TOYOTA JIDOSHA KABUSHIKI KAISHA, Toyota-shi (JP)

(72) Inventor: Tatsuji NAGAOKA, Nagakute-shi (JP)

(73) Assignee: TOYOTA JIDOSHA KABUSHIKI KAISHA, Toyota-shi (JP)

(21) Appl. No.: 16/015,141

(22) Filed: Jun. 21, 2018

(30) Foreign Application Priority Data
Jun. 23, 2017 (JP) 2017-123593

(51) Int. Cl. C23C 16/455; C23C 16/40

(52) U.S. Cl. CPC C23C 16/45563; C23C 16/40

(57) ABSTRACT

A film deposition apparatus for forming a film on a substrate is provided. The film deposition apparatus includes: a chamber in which the substrate is to be placed; a first heater configured to heat the chamber; a mist supply device configured to supply carrier gas including mist of source material solution of the film into the chamber; and a rectifier disposed within the chamber and configured to rectify a flow of the carrier gas including the mist. The rectifier includes a plurality of through holes through which the carrier gas flows, and the plurality of through holes extends toward the substrate placed in the chamber.

### TECHNICAL FIELD

A technique disclosed herein relates to a film deposition apparatus.

### BACKGROUND

There is a film deposition method known as a mist CVD (Chemical Vapor Deposition) method. In the mist CVD method, mist of source material solution of a film is supplied to a substrate along with carrier gas. The mist of the source material solution supplied to the substrate chemically reacts on the substrate, and thereby the film is deposited on the substrate. The mist CVD method is described, for example, in Japanese Patent Application Publication No. 2007-254869.

### SUMMARY

As one aspect of the mist CVD method, a method for depositing a film has been known, in which the substrate is placed in a heated chamber, carrier gas including mist of source material solution of the film is supplied into the chamber, and thereby the film is deposited on the substrate. In this film deposition method, since the film is deposited over an entire surface of the substrate at once, the film can be deposited over a relatively large area in a short period of time. On the other hand, the supplied mist is easily vaporized in the heated chamber, and due to this, convection may be generated within the chamber. If such convection occurs, a flow of the carrier gas within the chamber is disturbed, and as a result of this, homogeneity of the film deposited on the substrate is deteriorated. In view of this problem, the present disclosure provides a technique for suppressing disturbance of a carrier gas flow within a chamber.

The present technique is realized in a film deposition apparatus for forming a film on a substrate. This film deposition apparatus may comprise: a chamber in which the substrate is to be placed; a first heater configured to heat the chamber; a mist supply device configured to supply carrier gas including mist of source material solution of the film into the chamber; and a rectifier disposed within the chamber and configured to rectify a flow of the carrier gas including the mist. The rectifier may comprise a plurality of through holes through which the carrier gas flows. The plurality of through holes may extend toward the substrate placed in the chamber.

The above film deposition apparatus comprises the rectifier within the chamber. The plurality of through holes that extends toward the substrate is provided in the rectifier. The carrier gas including mist flows through the plurality of through holes, and thereby flow of the carrier gas is rectified toward the substrate. Due to this, disturbance of the flow of the carrier gas is suppressed near the substrate, and homogeneity of the film deposited on the substrate is enhanced.

### BRIEF DESCRIPTION OF DRAWINGS

FIG. 1 schematically shows a configuration of a film deposition apparatus 10 of a first embodiment.

FIGS. 2A and 2B show a rectifier 16. FIG. 2A is a front view and FIG. 2B is a side view.

FIG. 3 shows a state where an end face 16b of the rectifier 16 located at a downstream side makes an angle relative to a longitudinal direction X of the rectifier 16.

FIGS. 4A and 4B show variants of the rectifier 16. FIG. 4A shows a rectifier 16 in which a cross-section of through holes 17 has a rectangular shape. FIG. 4B shows a rectifier 16 in which a cross-section of through holes 17 has a hexagonal shape.

FIG. 5 shows a variant of the rectifier 16, and shows a state where an end face 16b of the rectifier 16 located at the downstream side makes an angle relative to the longitudinal direction X the rectifier 16.

FIG. 6 schematically shows a configuration of a film deposition apparatus 110 of a second embodiment.

FIG. 7 schematically shows a configuration of a film deposition apparatus 210 of a third embodiment.

### DETAILED DESCRIPTION

In one embodiment of the present technique, a temperature of the rectifier may be maintained within a range from minus 10 percent to plus 10 percent of a temperature of the substrate placed in the chamber. If the temperature of the rectifier is maintained at a same level as the temperature of the substrate, the mist of the source material solution is sufficiently pre-heated while passing through the rectifier, and the pre-heated mist can immediately react on the substrate (i.e., a film is deposited).

In addition to or alternative to the above embodiment, the temperature of the rectifier may be maintained at a higher temperature than the temperature of the substrate placed in the chamber. According to this configuration, air flow is generated from the rectifier having a relatively high temperature toward the substrate having a relatively low temperature, and thereby flow of the carrier gas including mist is further rectified toward the substrate.

In one embodiment of the present technique, the film deposition apparatus may further comprise a second heater configured to heat the rectifier. According to this configuration, the temperature of the rectifier can be adjusted to a desirable temperature more accurately.

In one embodiment of the present technique, an end face of the rectifier located at a downstream side may be parallel to the substrate placed in the chamber. According to this configuration, since a distance between the rectifier and the substrate is constant over an entirety of the substrate, the mist of the source material solution is homogeneously supplied to the entire substrate. Due to this, a homogeneous film can be deposited over the entire substrate.

In one embodiment of the present technique, the plurality of through holes of the rectifier may be inclined downward in the vertical direction from an upstream side toward the downstream side. According to this configuration, droplets of the source material solution (aggregation of the mist) adhering to inner walls of the through holes are smoothly discharged from the through holes by the flow of the carrier gas and the gravity acting on the droplets.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved film deposition apparatus as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### Embodiments

(First Embodiment) A film deposition apparatus 10 of a first embodiment will be described with reference to drawings. The film deposition apparatus 10 is an apparatus for depositing a film on a substrate 2. Oxide films such as a film of silicon oxide (SiO₂), aluminum oxide (Al₂O₃), and gallium oxide (Ga₂O₃) can be deposited in the film deposition apparatus 10. Alternatively, in the film deposition apparatus 10, crystals of semiconductor materials can be epitaxially grown on the substrate 2 as well. Materials of the film to be deposited by the film deposition apparatus 10 are not particularly limited.

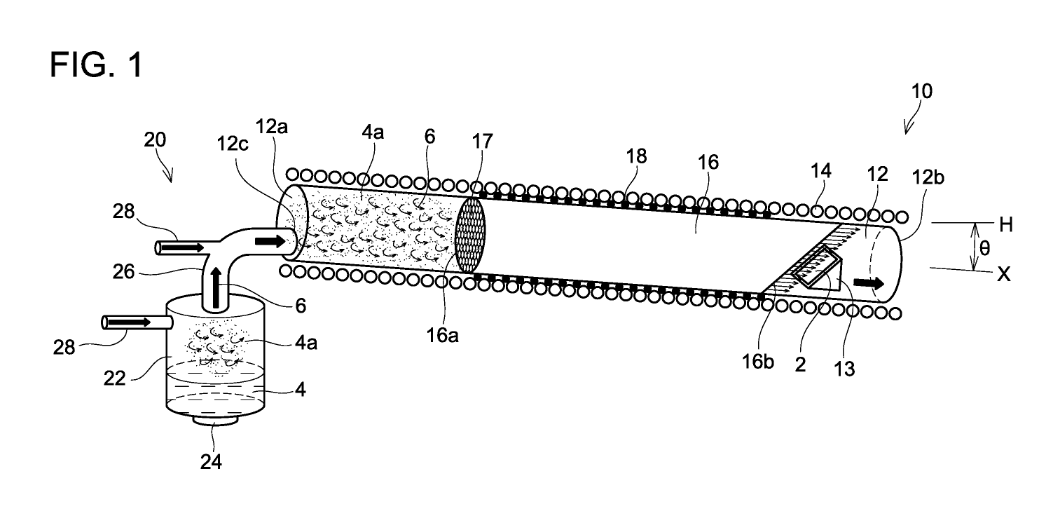

As shown in FIG. 1, the film deposition apparatus 10 comprises: a chamber 12 in which the substrate 2 is to be placed; a first heater 14 configured to heat the chamber 12; a mist supply device 20 connected to the chamber 12; a flow straightener 16 disposed within the chamber; and a second heater 18 configured to heat the flow straightener 16. It should be noted that since the flow straightener 16 disposed within the chamber 12 is heated also by the first heater 14, the second heater 18 is not necessarily needed. However, a temperature of the flow straightener 16 can be adjusted to a desirable temperature more accurately due to the presence of the second heater 18.

A specific configuration of the chamber 12 is not particularly limited. Although it is only an example, the chamber 12 of the present embodiment is a tubular chamber extending from an upstream end 12a to a downstream end 12b. A cross-section of the chamber 12 in a direction perpendicular to a longitudinal direction X of the chamber 12 has a circular shape. However, the cross-section of the chamber 12 is not limited to one of a circular shape. A mist supply port 12c to which the mist supply device 20 is connected is provided at the upstream end 12a of the chamber 12. The downstream end 12b of the chamber 12 is open. The longitudinal direction X of the chamber 12 is inclined with respect to a horizontal direction H, more specifically, the longitudinal direction X of the chamber 12 is inclined downward from the upstream end 12a toward the downstream end 12b. An angle θ formed by the longitudinal direction X of the chamber 12 and the horizontal direction H is not particularly limited, however, it may be set to an angle from 1 to 30 degrees, for example.

A substrate stage 13 that supports the substrate 2 is provided within the chamber 12. The substrate stage 13 is configured such that the substrate 2 is inclined with respect to the longitudinal direction X of the chamber 12. The substrate 2 supported by the substrate stage 13 may be at an angle from 30 to 60 degrees with respect to the longitudinal direction X of the chamber 12, although not particularly limited thereto. In the present embodiment, the substrate stage 13 is configured such that the substrate 2 is at an angle of 45 degrees with respect to the longitudinal direction X of the chamber 12. Moreover, as another embodiment, the substrate stage 13 may be configured such that the substrate 2 is disposed perpendicular to the longitudinal direction X of the chamber 12. Moreover, a third heater (not shown) configured to heat the substrate 2 may be provided in the substrate stage 13.

As described above, the first heater 14 is configured to heat the chamber 12. A specific configuration of the first heater 14 is not particularly limited. Although it is only an example, the first heater 14 of the present embodiment is an electric heater, and is disposed along an outer peripheral wall of the chamber 12. Due to this, the first heater 14 heats the outer peripheral wall of the chamber 12, and thereby heats the substrate 2 and the rectifier 16 within the chamber 12. A specific configuration of the second heater 18 is not particularly limited, either. Although it is only an example, the second heater 18 of the present embodiment is an electric heater, and is disposed along the outer peripheral wall of the chamber 12. The second heater 18 is provided only in a section of the chamber 12 where the rectifier 16 is disposed. In this respect, the second heater 18 is different from the first heater 14 which is provided over an entire length of the chamber 12. The second heater 18 is configured such that an operation of the second heater 18 is controllable independently of an operation of the first heater 14.

The mist supply device 20 is configured to supply carrier gas 6 including mist 4a of source material solution 4 of the film into the chamber 12. As described above, the mist supply device 20 is connected to the mist supply port 12c of the chamber 12, and the carrier gas 6 including the mist 4a is supplied from the mist supply port 12c into the chamber 12. A specific configuration of the mist supply device 20 is not particularly limited. Although it is only an example, the mist supply device 20 of the present embodiment comprises a solution bath 22 containing the source material solution 4, an ultrasonic vibrator 24 provided on the solution bath 22, a mist supply passage 26 that connects the solution bath 22 and the chamber 12, and a gas introduction passage 28 connected to the solution bath 22 or the mist supply passage 26. The gas introduction passage 28 is configured to supply the carrier gas 6 to the solution bath 22 or the mist supply passage 26. The ultrasonic vibrator 24 is configured to apply ultrasonic vibration to the source material solution 4 within the solution bath 22, and generate the mist 4a of the source material solution 4. The mist 4a of the source material solution 4 generated within the solution bath 22, is supplied to the chamber 12 via the mist supply passage 26 together with the carrier gas 6 introduced from the gas introduction passage 28.

The mist supply device 20 of the present embodiment is provided with two gas introduction passages 28, one of which is connected to the solution bath 22, and the other of which is connected to the mist supply passage 26. According to this configuration, the mist 4a are diffused (i.e., diluted) into the carrier gas 6 in a stepwise fashion, and thereby a concentration of the mist 4a in the carrier gas 6 supplied to the chamber 12 becomes stable. It should be noted that the mist supply device 20 only needs to include at least one gas introduction passage 28 connected to the solution bath 22, and a number and a structure of the other additional gas introduction passage(s) 28 are not particularly limited. Here, an inert gas such as nitrogen (N₂) gas may be used as the carrier gas 6. Further, a solution including a source material to be used in usual CVD method or epitaxial growth may be used as the source material solution 4 according to a kind of a film to be deposited.

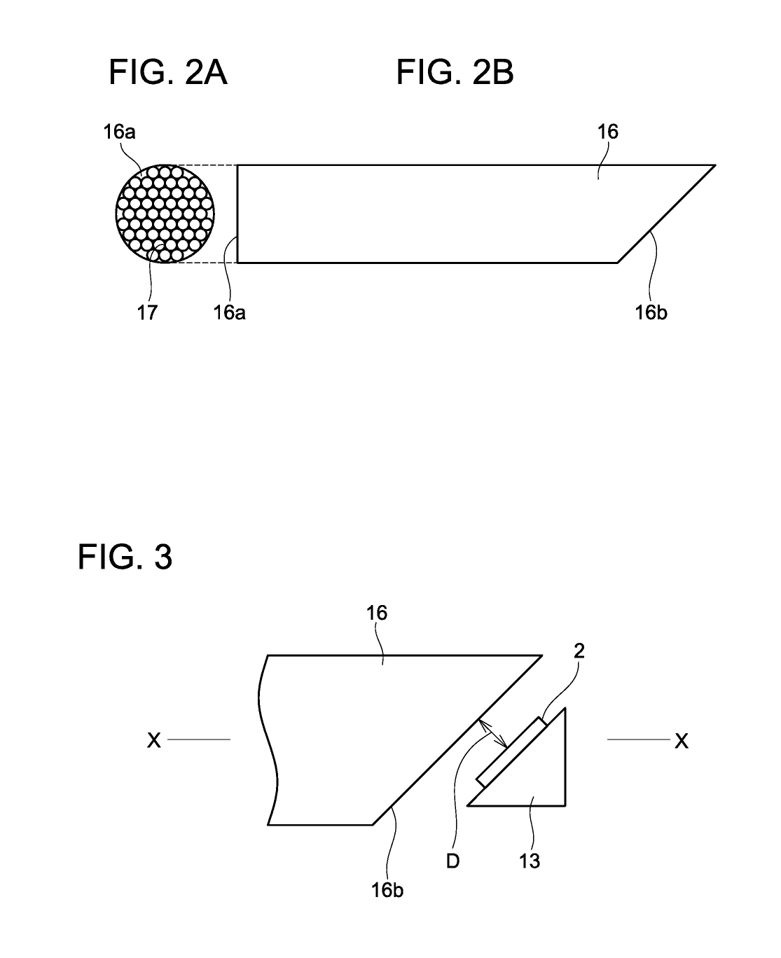

The rectifier 16 is configured to rectify a flow of the carrier gas 6 including the mist 4a within the chamber 12 toward the substrate 2 on the substrate stage 13. The rectifier 16 is positioned between the mist supply port 12c of the chamber 12 and the substrate stage 13. Although it is only an example, the rectifier 16 of the present embodiment has a cylindrical shape conforming to the shape of the tubular chamber 12. As shown in FIGS. 1, 2A and 2B, the rectifier 16 comprises a plurality of through holes 17. The plurality of through holes 17 extends from an end face 16a positioned at an upstream of the rectifier 16 to an end face 16b positioned at a downstream of the rectifier 16. Due to this, the carrier gas 6 including the mist 4a supplied into the chamber 12 is supplied to the substrate 2 on the substrate stage 13 after passing through the plurality of through holes 17.

The plurality of through holes 17 extends toward the substrate 2 on the substrate stage 13. Accordingly, the carrier gas 6 including the mist 4a is rectified toward the substrate 2 disposed within the chamber 12 by passing through the plurality of through holes 17 of the rectifier 16. Since disturbance of the flow of the carrier gas 6 is suppressed near the substrate 2, the mist 4a of the source material solution 4 is supplied homogeneously to the substrate 2 on the substrate stage 13. Due to this, since homogeneity of the film deposited on the substrate 2 is enhanced, a homogenous film can be deposited on the substrate 2 having a relatively large area. Here, in the rectifier 16 of the present embodiment, the plurality of through holes 17 is disposed parallel to each other, and each of the through holes 17 extends linearly. However, the plurality of through holes 17 may be curved, for example, so as to be formed into a gradual spiral shape in another embodiment.

Although it is only one example, the rectifier 16 in the present embodiment is disposed away from the mist supply port 12c of the chamber 12. Due to this, a space for homogenously mixing the mist 4a and the carrier gas 6 is provided between the mist supply port 12c and the rectifier 16. Accordingly, an orientation and a shape of the mist supply port 12c may be designed such that the flow of the carrier gas 6 is disturbed to some extent in the space between the mist supply port 12c and the rectifier 16.

As shown in FIG. 3, in the rectifier 16 in the present embodiment, the end face 16b at a downstream side is inclined relative to the longitudinal direction X of the rectifier 16, and is parallel to the substrate 2 on the substrate stage 13. Due to this, a distance D between the rectifier 16 and the substrate 2 is constant over an entirety of the substrate 2, and thus the mist 4a of the source material solution 4 is supplied to the entirety of the substrate 2 homogenously.

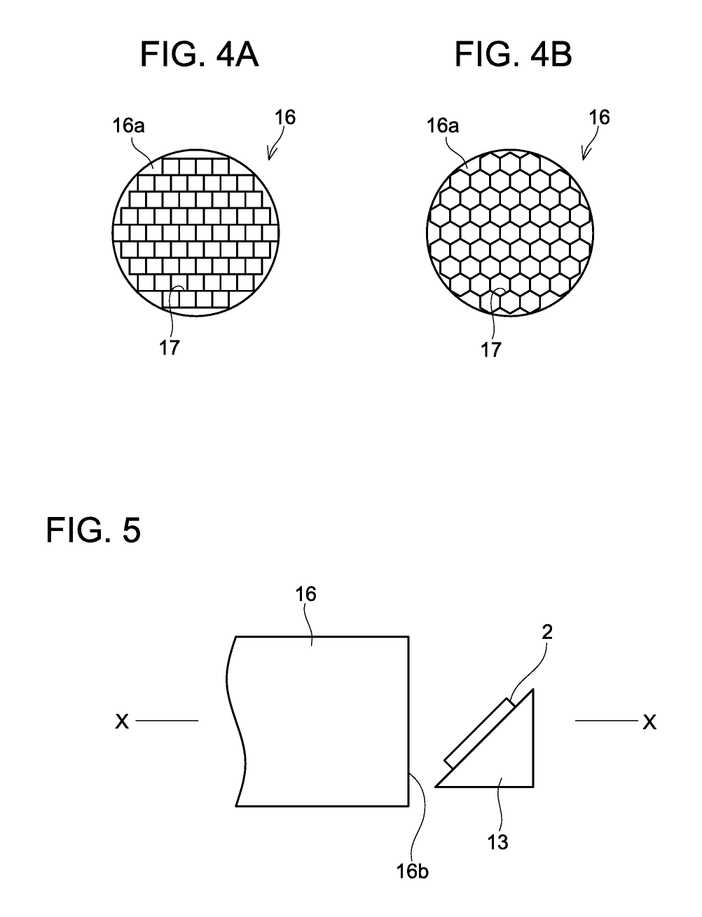

A cross-sectional shape of the through holes 17 of the rectifier 16 is not particularly limited. As shown in FIGS. 2A and 2B, for example, the through holes 17 of the rectifier 16 in the present embodiment have a circular cross-sectional shape. If the through holes 17 have the circular cross-sectional shape, motion components of the mist 4a can be adjusted isotopically within a cross-section of the through holes 17 when the carrier gas 6 including the mist 4a passes through the through holes 17. In another embodiment, as shown in FIG. 4A, each of the through holes 17 may have a rectangular cross section, and the plurality of the through holes 17 may be arranged in a lattice pattern. In another embodiment, as shown in FIG. 4B, each of the through holes 17 may have a hexagonal cross section, and the plurality of the through holes 17 may be arranged in a honeycomb pattern. Since the hexagonal cross section is similar to the circular cross section, the motion components of the mist 4a can be adjusted almost isotopically within the cross-section of the through holes 17. Further, when the plurality of through holes 17 is arranged in the lattice or honeycomb pattern, a thickness of a wall defining each of the through holes 17 becomes constant. Thus, the flow of the carrier gas 16 including the mist 4a becomes more homogenous within the cross section of the chamber 12. In another embodiment, the through holes 17 of the rectifier 16 may have an oval, octagonal or the other cross-sectional shape.

As described above, in the rectifier 16 of the present embodiment, the end face 16b disposed at the downstream side is inclined relative to the longitudinal direction X of the chamber 12 (see FIG. 3). However, as shown in FIG. 5, the end face 16b of the rectifier 16 disposed at the downstream side may be perpendicular to the longitudinal direction X of the chamber 12. An angle formed by the end face 16b of the rectifier 16 disposed at the downstream side relative to the longitudinal direction X of the chamber 12 is not particularly limited.

The substrate 2 and the rectifier 16 in the chamber 12 are heated by the first heater 14. The rectifier 16 is further heated by the second heater 18 as well. Specific configurations of the first heater 14 and the second heater 18 may be designed as appropriate according to each of target temperatures of the substrate 2 and the rectifier 16. Each of the target temperatures of the substrate 2 and the flow rectifier 16 is not particularly limited. In one embodiment, a temperature of the rectifier 16 may be maintained within a range from minus 10 percent to plus 10 percent of a temperature of the substrate 2 placed in the chamber 12. If the temperature of the rectifier 16 is maintained at a same level as the substrate 2, the mist 4a of the source material solution 4 is sufficiently pre-heated while the mist 4a passes through the rectifier 16. If the mist 4a is sufficiently pre-heated, the mist 4a that reaches the substrate 2 can react quickly on the substrate 2 (i.e., a film can be deposited).

Additionally or alternatively, the temperature of the rectifier 16 may be maintained at a higher temperature than the temperature of the substrate 2 placed in the chamber 12. According to this configuration, since a flow of air is generated from the rectifier 16 having a relatively high temperature toward the substrate 2 having a relatively low temperature, the flow of the carrier gas 6 including the mist 4a is further rectified toward the substrate 2. In the film deposition apparatus 10 of the present embodiment, the temperature of the rectifier 16 can be raised independently of the temperature of the substrate 2 by the second heater 18 that heats the rectifier 16. However, in another embodiment, the second heater 18 is not necessarily needed, and the temperature of the rectifier 16 can be maintained at a higher temperature than the temperature of the substrate 2 in the chamber 12 using only the first heater 14.

In the film deposition apparatus 10 of the present embodiment, as described above, the longitudinal direction X of the chamber 12 is inclined relative to the horizontal direction H. Due to this, the rectifier 16 disposed in the chamber 12 is also inclined relative to the horizontal direction H, and the through holes 17 of the rectifier 16 are inclined downward in the vertical direction from an upstream side toward the downstream side. According to this configuration, liquid droplets of the source material solution 4 (aggregation of the mist 4a) that adhere to inner walls of the through holes 17 are smoothly discharged from the through holes 17 by both the flow of the carrier gas 6 and the gravity acting on the liquid droplets. The through holes 17 can be prevented from being clogged with the source material solution 4 since the source material solution 4 is discharged from the through holes 17.

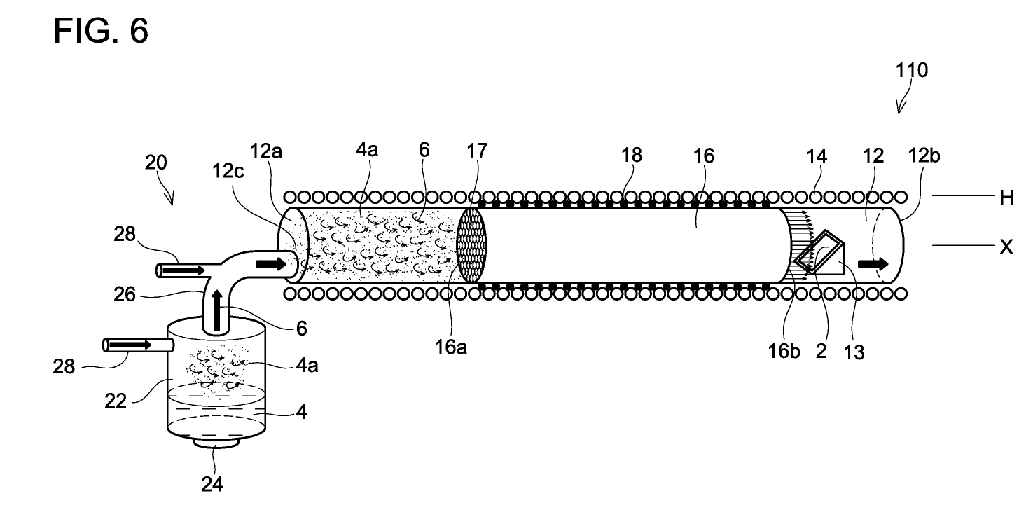

(Second Embodiment) A film deposition apparatus 110 of the second embodiment will be described with reference to FIG. 6. The film deposition apparatus 110 in the present embodiment is also an apparatus for depositing a film on the substrate 2. Similar to the film deposition apparatus 10 of the first embodiment, the film deposition apparatus 110 in the present embodiment comprises the chamber 12 in which the substrate 2 is to be placed; the first heater 14 configured to heat the chamber 12; the mist supply device 20 connected to the chamber 12; the rectifier 16 disposed within the chamber 12; and the second heater 18 configured to heat the rectifier 16. The stage 13 that supports the substrate 2 is provided within the chamber 12. The mist supply device 20 is configured to supply the carrier gas 6 including the mist 4a of the source material solution 4 into the chamber 12. The rectifier 16 comprises the plurality of through holes 17 that extends toward the substrate 2 on the substrate stage 13, and is configured to rectify the flow of the carrier gas 6 including the mist 4a toward the substrate 2 on the substrate stage 13. The film deposition apparatus 110 in the present embodiment has same configurations as the film deposition apparatus 10 in the first embodiment except for the points to be described below. Thus, regarding the same configurations as those of the film deposition apparatus 10 of the first embodiment, the explanation of the first embodiment is hereby incorporated by reference, and redundant explanation will be omitted.

In the film deposition apparatus 110 of the present embodiment, the longitudinal direction X of the chamber 12 is parallel to the horizontal direction H. The film deposition apparatus 110 differs from the film deposition apparatus 10 of the first embodiment in this point. As such, the longitudinal direction X of the chamber 12 may not necessarily be inclined relative to the horizontal direction H. Further, the end face 16b of the rectifier 16 at the downstream side is perpendicular to the longitudinal direction X of the chamber 12. The film deposition apparatus 110 differs from the film deposition apparatus 10 of the first embodiment also in this point. As such, the end face 16b of the rectifier 16 at the downstream side may not necessarily be inclined to the longitudinal direction X of the chamber 12.

In the film deposition apparatus 110 of the second embodiment as well, the flow of the carrier gas 6 including the mist 4a is rectified toward the substrate 2 disposed in the chamber 12 when the carrier gas 6 including the mist 4a passes through the through holes 17 of the rectifier 16. Since disturbance of the carrier gas 6 is suppressed near the substrate 2, the mist 4a of the source material solution 4 is supplied homogenously to the substrate 2 on the substrate stage 13. Due to this, since homogeneity of the film deposited on the substrate 2 is enhanced, a homogenous film can be deposited on the substrate 2 having a relatively large area.

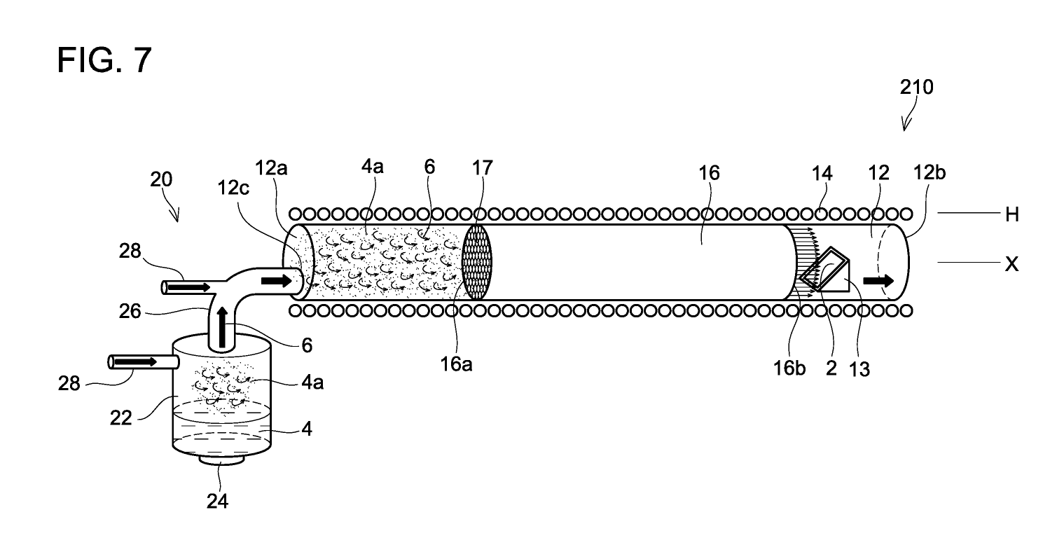

(Third Embodiment) A film deposition apparatus 210 of the third embodiment will be described with reference to FIG. 7. The film deposition apparatus 210 of the present embodiment is also an apparatus for depositing a film on the substrate 2. Similar to the film deposition apparatuses 10, 110 of the first and second embodiments, the film deposition apparatus 210 of the present embodiment comprises: the chamber 12 in which the substrate 2 is to be placed; the first heater 14 configured to heat the chamber 12; the mist supply device 20 connected to the chamber 12; and the rectifier 16 disposed within the chamber 12. The stage 13 that supports the substrate 2 is provided in the chamber 12. The mist supply device 20 is configured to supply the carrier gas 6 including the mist 4a of the source material solution 4 to the chamber 12. The rectifier 16 comprises the plurality of through holes 17 that extends toward the substrate 2 on the substrate stage 13, and is configured to rectify the flow of the carrier gas 6 including the mist 4a toward the substrate 2 on the substrate stage 13. The film deposition apparatus 210 of the present embodiment has same configurations as the film deposition apparatus 110 of the second embodiment except for the points to be described below. Thus, regarding the same configurations as those of the film deposition apparatus 110 of the second embodiment, the explanations of the first and second embodiments are hereby incorporated by reference, and redundant explanation will be omitted.

The film deposition apparatus 210 of the present embodiment does not comprise a second heater 18, and the film deposition apparatus 210 differs from the film deposition apparatus 110 of the first embodiment in this point. As such, the film deposition apparatus 210 does not necessarily need to comprise the second heater 18. The rectifier 16 in the chamber 12 can be heated by the first heater 14 even without the presence of the second heater 18. Further, the temperature of the rectifier 16 can be maintained within a range from minus 10 percent to plus 10 percent of the temperature of the substrate 2 placed in the chamber 12 even without the presence of the second heater 18 when the first heater 14 is appropriately designed. Alternatively, the temperature of the rectifier 16 can be maintained at a higher temperature than the temperature of the substrate 2 placed in the chamber 12.

In the film deposition apparatus 210 of the third embodiment as well, the flow of the carrier gas 6 including the mist 4a is rectified toward the substrate 2 disposed in the chamber 12 by the carrier gas 6 including the mist 4a passing through the through holes 17 of the rectifier 16. Since disturbance of the carrier gas 6 is suppressed near the substrate 2, the mist 4a of the source material solution 4 is supplied homogenously to the substrate 2 on the substrate stage 13. Due to this, since homogeneity of the film deposited on the substrate 2 is enhanced, a homogenous film can be deposited on the substrate 2 having a relatively large area.

What is claimed is:

1. A film deposition apparatus for forming a film on a substrate, the film deposition apparatus comprising:
a chamber in which the substrate is to be placed;
a first heater configured to heat the chamber;
a mist supply device configured to supply carrier gas including mist of source material solution of the film into the chamber; and
a rectifier disposed within the chamber and configured to rectify a flow of the carrier gas including the mist;
wherein the rectifier comprises a plurality of through holes through which the carrier gas flows, the plurality of through holes extending toward the substrate placed in the chamber.

2. The film deposition apparatus according to claim 1, wherein a temperature of the rectifier is configured to be maintained within a range from minus 10 percent to plus 10 percent of a temperature of the substrate placed in the chamber.

3. The film deposition apparatus according to claim 1, wherein the temperature of the rectifier is configured to be maintained at a higher temperature than the temperature of the substrate placed in the chamber.

4. The film deposition apparatus according to claim 1, further comprising a second heater configured to heat the rectifier.

5. The film deposition apparatus according to claim 1, wherein an end face of the rectifier located at a downstream side is parallel to the substrate placed in the chamber.

6. The film deposition apparatus according to claim 1, wherein the plurality of through holes of the rectifier is inclined downward in the vertical direction from an upstream side toward a downstream side.
